(19) United States
(12) Patent Application Publication
(10) Pub. No.: US 2026/0140448 A1
(43) Pub. Date: May 21, 2026

(54) UNDERLAYER COMPOSITION FOR USE IN MANUFACTURING ELECTRONIC DEVICES

(71) Applicant: DuPont Electronic Materials International, LLC, Marlborough, MA (US)

(72) Inventor: Soojung Clara Leem, Hwaseong (KR)

(21) Appl. No.: 18/953,395

(22) Filed: Nov. 20, 2024

(51) Int. Cl. G03F 7/09; G03F 7/00; G03F 7/16; H01L 21/027

(52) U.S. Cl. CPC G03F 7/094; G03F 7/16; G03F 7/70025; G03F 7/70033; H10P 76/20

(57) ABSTRACT

Disclosed herein is a coating composition for use with an overcoated photoresist composition, comprising: a thermally crosslinkable resin; a compound of the following general formula (1):

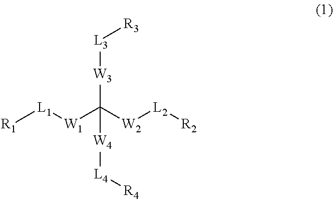

wherein: W₁, W₂, W₃, and W₄ are independently a single bond or substituted or unsubstituted C₁₋₅ alkylene; L₁ and L₂ are each an ester group; L₃ and L₄ are independently a single bond or a group chosen from carbonyl, or an ester group; R₁ and R₂ are independently hydrogen, halogen, substituted or unsubstituted C₁₋₁₀ alkyl, or substituted or unsubstituted C₃₋₁₀ cycloalkyl; R₃ and R₄ are independently hydrogen, halogen, hydroxyl, substituted or unsubstituted C₁₋₁₀ alkyl, or substituted or unsubstituted C₃₋₁₀ cycloalkyl; and a solvent.

### FIELD

The present invention relates to a manufacturing of electronic devices, and more specifically, to materials for use in semiconductor manufacture.

### BACKGROUND

Underlayer compositions (or resist underlayer compositions) can be used in the semiconductor industry as etch masks for lithography in advanced technology nodes for integrated circuit manufacturing. In photolithography in manufacture of electronic devices, images are formed and developed in resist layers and then the image is transferred to an underlying substrate. The processes can involve multiple layers. For example, underlayer compositions (e.g., Bottom anti-reflective coatings or BARC) may be applied between the substrate and a photoresist layer.

As the electronic device structures become more intricate and complex with a higher density of features, the size of the features decreases. With these changes the underlayer (or resists underlayer) has also become more important than before in different applications. Among the various roles of underlayer, one of the key challenges has been filling of very narrow trenches, holes, spacings and other topographies in substrates to flatten the surface underneath the resist and to protect the intentionally formed trenches from subsequent processes which can damage the structures on the substrate.

For example, if the underlayer is inadequate in filling gaps and planarizing, the formation of voids in gaps may lead to patterning defects during imaging of overcoated photoresist layer when the resist underlayer serves to minimize the substrate reflection as classical bottom antireflective coating (BARC). In addition to reduced device yields from lithography failures, void formation can further increase defects by allowing current leakage between adjacent devices and damage of the device and substrate in following process such as dry and wet etching. Conventional resist underlayer formulations are not capable of filling such gaps with high aspect ratio (depth:width) and narrow width.

While there have been previously developed formulations with specified resin structures targeted to achieve such properties, there remains a desire for a formulation that can be applied for various resins with other properties need to be retained such as optical properties, dry etch rate, heat resistance and others.

### BRIEF DESCRIPTION OF THE DRAWINGS

FIG. 1 shows photographs of scanning electron microscope scans as discussed in the Examples.

### SUMMARY

Disclosed herein is a coating composition for use with an overcoated photoresist composition, comprising: a thermally crosslinkable resin; a compound of the following general formula (1):

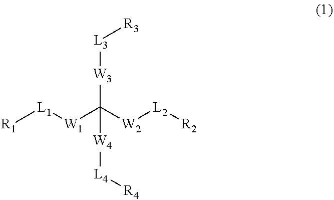

wherein: W₁, W₂, W₃, and W₄ are independently a single bond or substituted or unsubstituted C₁₋₅ alkylene; L₁ and L₂ are each an ester group; L₃ and L₄ are independently a single bond or a group chosen from carbonyl, or an ester group; R₁ and R₂ are independently hydrogen, halogen, substituted or unsubstituted C₁₋₁₀ alkyl, or substituted or unsubstituted C₃₋₁₀ cycloalkyl; R₃ and R₄ are independently hydrogen, halogen, hydroxyl, substituted or unsubstituted C₁₋₁₀ alkyl, or substituted or unsubstituted C₃₋₁₀ cycloalkyl; and a solvent.

Also disclosed is a pattern formation method, comprising: (a) forming on a substrate an underlayer from an underlayer composition as disclosed herein; (b) applying a photoresist layer over the underlayer; (c) exposing the photoresist layer to activating radiation; and (d) developing the exposed photoresist layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below to explain aspects of the present description.

The underlayer composition as disclosed herein can form films which can protect underlying substrates during various pattern transfer and etch processes and/or provide a film has sufficient planarization properties to provide the film with a relatively flat top surface if the underlying layer or substrate includes various pitch, various line/space patterns, and/or various trench depths.

The underlayer composition include a thermally cross-linkable resin, a compound of formula (I), and a solvent.

The thermally cross-linkable resin can be a resin used in resist coating compositions. The polymeric backbone of the resin can comprise a polyester, an acrylic polymer, a vinyl polymer (such as a styrenic polymer or a vinyl ether polymer), a novolac resin, a polynorbornene, a polyacetal, a polyethylene glycol, a polyamides, a polyacrylamide, a polyphenol a polyvinyl alcohol, copolymers thereof, or mixtures thereof. The thermally cross-linkable polymer includes one or more cross-linkable groups such as, for example, a hydroxyl, a carboxyl, a thiol, an amine, an epoxy, an alkoxy, an amide or an ethylenically unsaturated group. The resin can be included in the formulation as the mixture of one or more resins as described above. The thermally cross-linkable resin can have a weight average molecular weight (Mw) ranging from 500 to 10,000 grams/mole. Molecular weight can be determined by gel permeation chromatography using a polystyrene standard.

The total amount of such resin(s) can be present in the composition, for example, in amounts of from 0.1, from 0.5, from 1 up to 20, up to 15, up to 10 weight percent (wt %) based on total weight of the composition.

The composition further comprises an additive compound of formula (I):

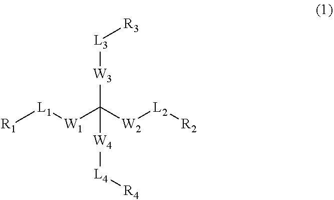

wherein: W₁, W₂, W₃, and W₄ are independently a single bond or substituted or unsubstituted C₁₋₅ alkylene; L₁ and L₂ are each an ester group; L₃ and L₄ are independently a single bond or a group chosen from carbonyl, or an ester group; R₁ and R₂ are independently hydrogen, halogen, substituted or unsubstituted C₁₋₁₀ alkyl, or substituted or unsubstituted C₃₋₁₀ cycloalkyl; R₃ and R₄ are independently hydrogen, halogen, hydroxyl, substituted or unsubstituted C₁₋₁₀ alkyl, or substituted or unsubstituted C₃₋₁₀ cycloalkyl. Where a group is substituted specific examples of substituent groups include nitro, cyano, amino, thio, C1-6 alkylthio or C1-6 haloalkyl groups. R₃ is preferably hydroxyl. In certain embodiments, W₃ and L₃ are preferably each a single bond. In other preferred embodiments L₃ is an ester group. Compound(s) of general formula (1) can be present in the composition in an amount of from 0.1, from 0.5, from 1 up to 20, up to 15, up to 12, or up to 10 wt % based on total weight of the coating composition.

Specific examples of the compound of formula (1), include formulas (2)-(60):

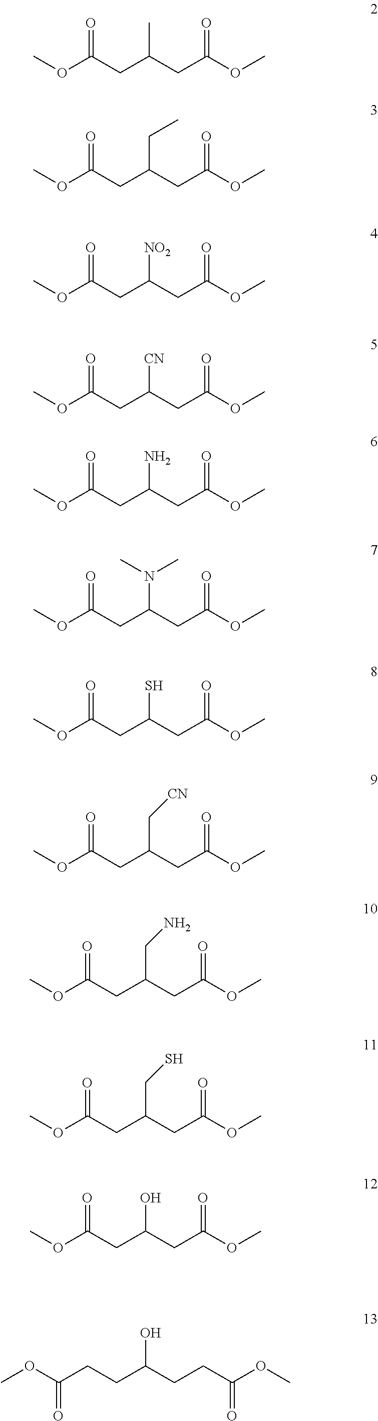

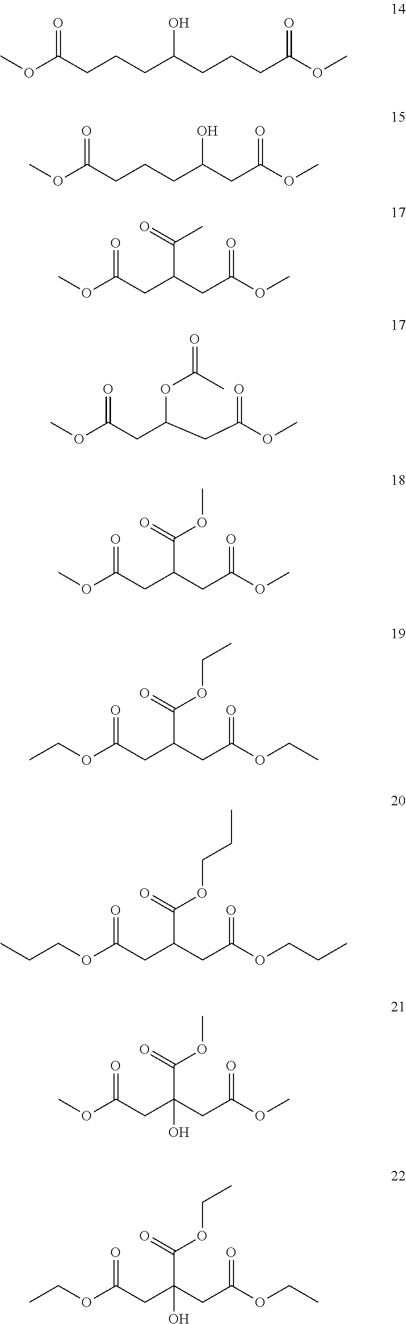

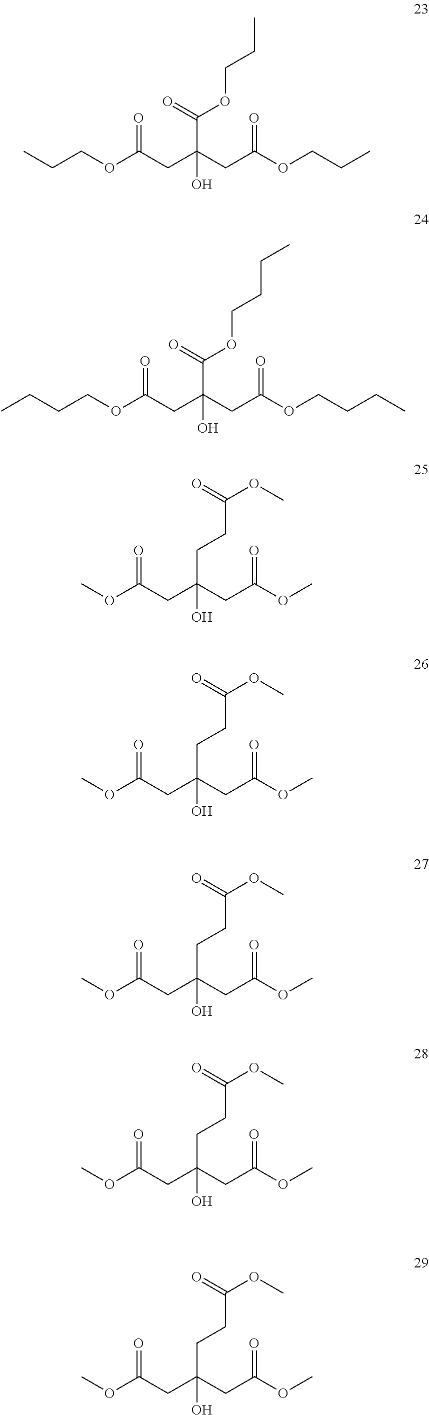

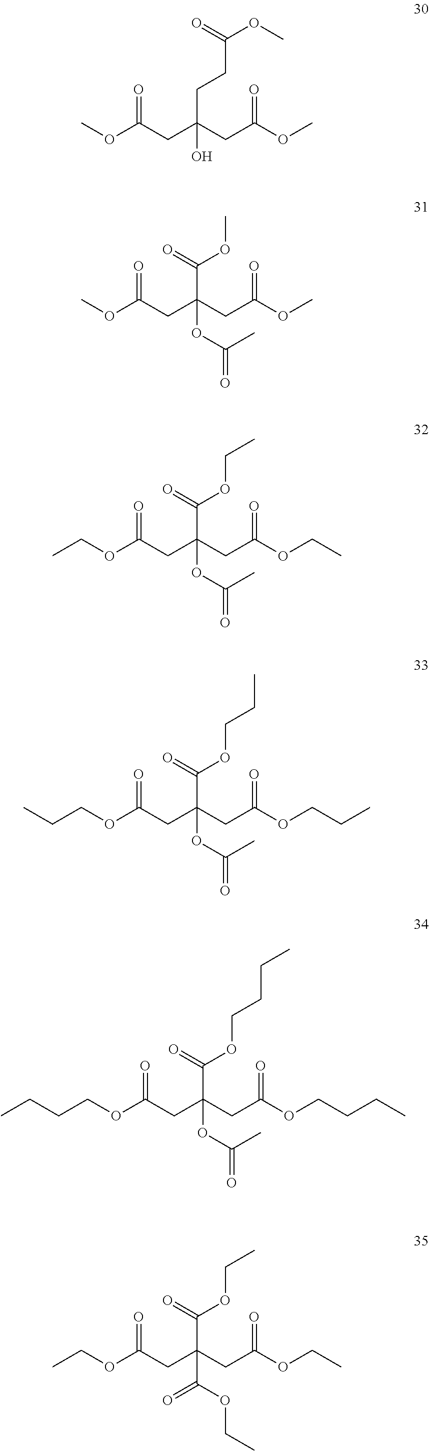

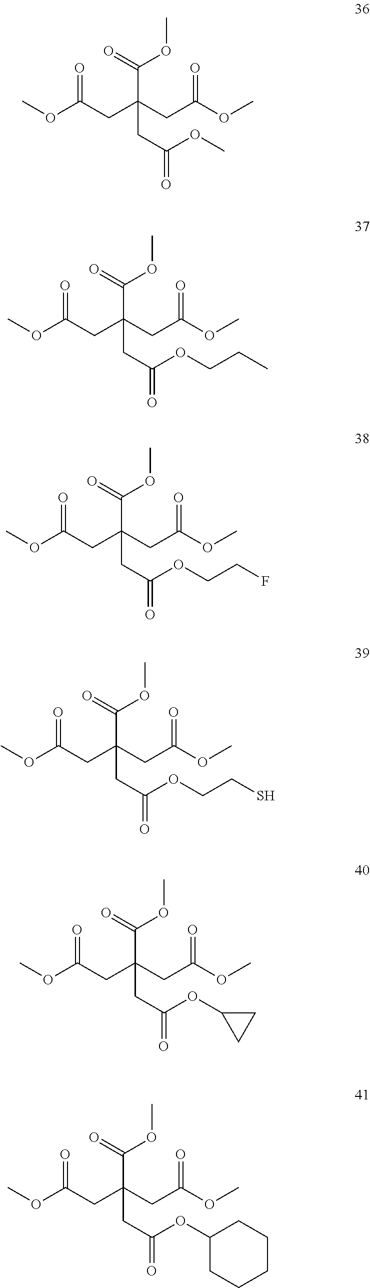

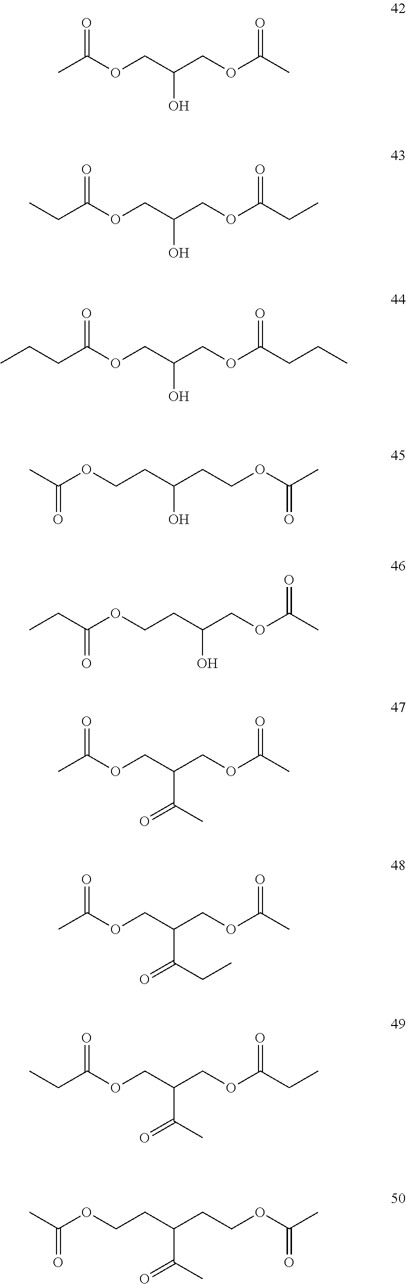

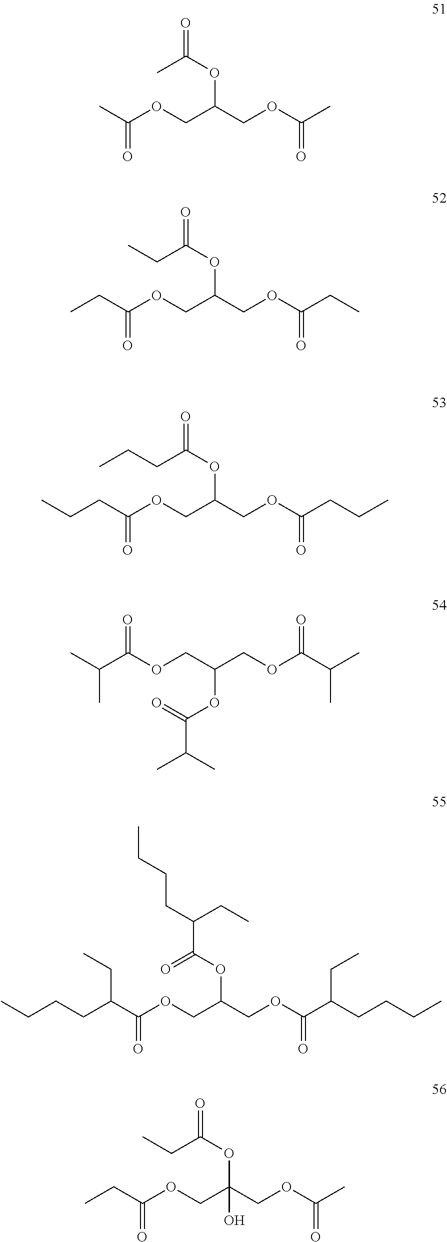

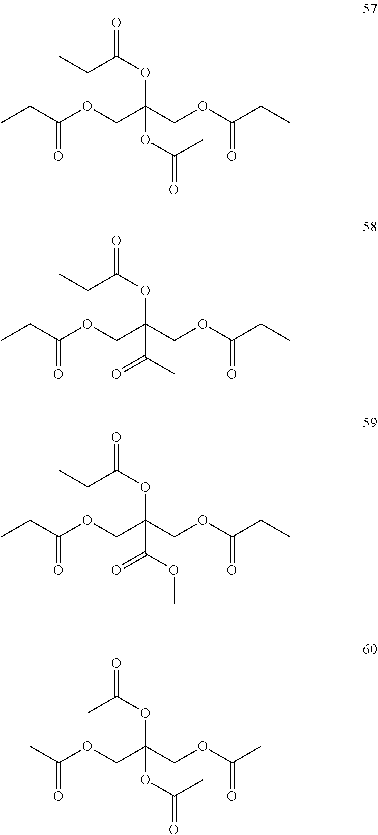

The underlayer composition includes a solvent. The solvent component may be a single solvent or may include a mixture of two or more distinct solvents. Suitably, each of the multiple solvents may be miscible with each other. Suitable solvents include, for example, one or more oxyisobutyric acid esters, particularly methyl-2-hydroxyisobutyrate, 2-hydroxyisobutyric acid, and ethyl lactate; one or more of glycol ethers, particularly 2-methoxyethyl ether (diglyme), ethylene glycol monomethyl ether, and propylene glycol monomethyl ether; one or more solvents that have both ether and hydroxy moieties, particularly methoxy butanol, ethoxy butanol, methoxy propanol, and ethoxy propanol; one or more alkyl esters, particularly methyl cellosolve acetate, ethyl cellosolve acetate, propylene glycol monomethyl ether acetate, and dipropylene glycol monomethyl ether acetate and other solvents such as one or more dibasic esters; and/or other solvents such as one or more of propylene carbonate, cyclohexanone, and gamma-butyrolactone.

The amount of solvent in the composition can be, for example, from 60, from 65, from 70 up to 99.9, up to 99 weight percent based on total weight of the composition.

In some aspects, the underlayer composition may further include one or more curing agents to aid in the curing of the underlayer composition, for example after the underlayer composition has been applied to a surface. A curing agent is any component which causes curing of the underlayer composition on the surface of a substrate.

It may be beneficial to include an acid generator compound such as a photoacid generator (PAG) and/or a thermal acid generator (TAG) compound in the underlayer compositions. Preferred curing agents are thermal acid generators (TAGs).

Suitable PAGs are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

A TAG compound is any compound that liberates acid upon exposure to heat. Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators.

Suitable TAG compounds may include, for example, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, trifluoromethylbenzenesulfonic acid, perfluorobutane sulfonic acid; particular onium salts, and paratoluene sulfonic acid-trimethylpyridinium salt (disclosed in US20170336709). A variety of aromatic (anthracene, naphthalene, or benzene derivatives) sulfonic acid amine salts can be employed as the TAG, including those disclosed in U.S. Pat. Nos. 3,474,054, 4,200,729, 4,251,665 and 5,187,019. Examples of TAGs include those sold by King Industries, Norwalk, Conn. USA under NACURE, CDX and K-PURE names, for example, NACURE 5225, CDX-2168E, K-PURE 2678 and KPURE 2700. One or more of such TAGs can be used.

The amount of such curing agents (if used) in the present compositions may be, for example, from greater than 0, from 0.01, from 0.02, from 0.03 up to 5, up to 3, or up to 1 weight percent based on total weight of the underlayer composition.

In some aspects, the underlayer composition does not include a photoacid generator. Accordingly, in these embodiments the underlayer composition may be substantially free of a PAG compound and/or a polymeric PAG, for example free of a PAG compound or polymeric PAG.

The underlayer composition may further include one or more crosslinking agents. Any suitable crosslinking agent may be further used in the present coating compositions, provided that such crosslinking agent has at least 2, and preferably at least 3, moieties capable of reacting with functional groups in the underlayer composition. Exemplary crosslinking agents may include novolac resins, acrylate resins, vinyl resins, melamine compounds, guanamine compounds, isocyanate-containing compounds, benzocyclobutenes, benzoxazines, and the like, and typically any of the foregoing having 2 or more, more typically 3 or more substituents selected from methylol, C₁₋₁₀ alkoxymethyl, C₂₋₁₀ acyloxymethyl, and C₃₋₁₀ heterocycles. Examples of suitable crosslinking agents include tetramethoxyglocoluril (TMGU) and those shown below:

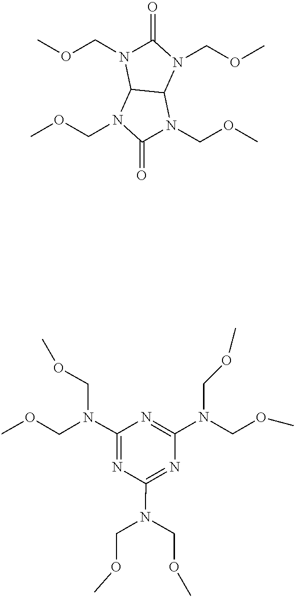

The additional crosslinking agents are well-known in the art and are commercially available from a variety of sources. The amount of such additional crosslinking agents (if present) in the present coating compositions may be, for example, in the range from greater than 0, from 0.1, from 0.2 or from 0.3 up to 5, up to 4 or up to 3 weight percent based on total weight of the coating composition.

The underlayer composition may include one or more optional additives, for example, surfactants, or the like. When present, each optional additive may be used in the underlayer composition in minor amounts such as from 0.01, from 0.05, from 0.1 up to 5, up to 4, up to 3, up to 2, or up to 1 weight percent based on total weight of the underlayer composition.

Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Mich. USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, Pa. and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.).

The desired total solids of the underlayer composition will depend on factors such as the desired final layer thickness. Typically, the total solids of the underlayer composition may be from 0.1 to 20 wt %, for example, from 0.1 to 10 wt %, more typically, from 0.11 to 8 wt %, based on the total weight of the coating composition. By solids in the composition is meant components that remain in the film after removal (e.g. by evaporation) of the solvent after forming the underlayer film or coating. The solids will include the resin(s), cross-linker, and optional components such as TAG, PAG and surfactant.

The underlayer composition may be prepared following known procedures. For example, the underlayer composition may be prepared by combining the resin, the compound of formula (I), the solvent, and any optional components, in any order. The underlayer composition may be used as is, or may be, subjected to purification or dilution prior to being coated on the substrate. Purification may involve, for example, one or more of centrifugation, filtration, distillation, decantation, evaporation, treatment with ion exchange beads, and the like.

The patterning methods of the present invention comprise applying a layer of the underlayer composition over a substrate; curing the applied underlayer composition to form a coated underlayer; and forming a photoresist layer over the coated underlayer. The method may further include the steps of pattern-wise exposing the photoresist layer to activating radiation; and developing the exposed photoresist layer to provide a resist relief image. In some aspects, the method may further include forming a silicon-containing layer, an organic antireflective coating layer, or a combination thereof, over the coated underlayer prior to forming the photoresist layer. In some aspects, the method may further include transferring the pattern to the silicon-containing layer, the organic antireflective coating layer, or the combination thereof, after developing an exposed photoresist layer and before the step transferring the pattern to the coated underlayer.

A wide variety of substrates may be used in the patterning methods, with electronic device substrates being typical. Suitable substrates include, for example, packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Such substrates may be any suitable size. Typical wafer substrate diameters are 200 mm to 300 mm, although wafers having smaller and larger diameters may be suitably employed according to the present invention. As used herein, the term “semiconductor substrate” includes any substrate having one or more semiconductor layers or structures which may optionally include active or operable portions of semiconductor devices. A semiconductor device refers to a semiconductor substrate upon which at least one microelectronic device has been or is being batch fabricated.

The substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. The substrate may include one or more layers and patterned features. The layers may include, for example, one or more conductive layers such as layers of aluminum, copper, molybdenum, tantalum, titanium, tungsten, alloys, nitrides, or silicides of such metals, doped amorphous silicon or doped polysilicon, one or more dielectric layers such as layers of silicon oxide, silicon nitride, silicon oxynitride, or metal oxides, metal nitrides, semiconductor layers, such as single-crystal silicon, and combinations thereof. In some aspects, the substrate includes titanium nitride. The layers can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating.

It may be desired in certain patterning methods of the invention to provide one or more lithographic layers such as a hardmask layer, for example, a spin-on-carbon (SOC), amorphous carbon, or metal hardmask layer, a CVD layer such as a silicon nitride (SiN) layer, silicon oxide (SiO) layer, or silicon oxynitride (SiON) layer, an organic or inorganic BARC layer, or a combination thereof, on an upper surface of the substrate prior to forming the underlayer of the invention. Such layers, together with a layer of the underlayer composition of the invention and photoresist layer, form a lithographic material stack. Typical lithographic stacks which may be used in the patterning methods of the invention include, for example, the following: underlayer/photoresist; underlayer/metal hardmask layer/photoresist; underlayer/metal hardmask layer/underlayer/photoresist; underlayer/SOC layer/photoresist layer; SOC layer/underlayer/photoresist layer; SOC layer/SiON layer/underlayer/photoresist layer; SOC layer/SiARC layer/underlayer/photoresist layer; SOC layer/metal hardmask layer/underlayer/photoresist layer; amorphous carbon layer/underlayer/photoresist layer; and amorphous carbon layer/SiON layer/underlayer/photoresist layer.

It is to be understood that the “underlayer,” as used herein, refers to the one or more layers that are disposed between the substrate and the photoresist layer (i.e., “above the substrate”). Accordingly, the inventive coated underlayer (i.e., a layer of the underlayer composition) may be used alone as a underlayer, or the inventive coated underlayer (i.e., a layer of the underlayer composition) may be used in conjunction with other underlayers, including those as described herein.

The underlayer composition may be coated on the substrate by any suitable means, such as spin-coating, slot-die coating, doctor blading, curtain-coating, roller-coating, spray-coating, dip-coating, and the like. In the case of a semiconductor wafer, spin-coating is preferred. In a typical spin-coating method, the present compositions are applied to a substrate which is spinning at a rate of 500 to 4000 revolutions per minute (rpm) for a period of 15 to 90 seconds to obtain a desired layer of the condensed polymer on the substrate. It will be appreciated by those skilled in the art that the thickness of the coated layer may be adjusted by changing the spin speed, as well as the solids content of the composition. An underlayer formed from the underlayer composition typically has a dried layer thickness from 1 up to 500, up to 400, up to 300, or up to 200 nanometers (nm).

The coated underlayer composition is optionally softbaked at a relatively low temperature to remove any solvent and other relatively volatile components. Typically, the substrate is baked at a temperature of less than or equal to 150° C., preferably from 60 to 125° C., and more preferably from 90 to 115° C. The baking time is typically from 10 seconds to 10 minutes, preferably from 30 seconds to 5 minutes, and more preferably from 60 seconds to 90 seconds. When the substrate is a wafer, such baking step may be performed by heating the wafer on a hot plate. Such soft-baking step may be performed as part of the curing of the coating layer, or may be omitted altogether.

The underlayer composition is then cured to form a coated underlayer. The coating composition should be sufficiently cured such that the coated underlayer film does not intermix, or minimally intermixes, with another underlayer component or the photoresist layer to be formed above the underlayer. The coated composition may be cured in an oxygen-containing atmosphere, such as air, or in an inert atmosphere, such as nitrogen and under conditions, such as heating, sufficient to provide a cured coating layer. This curing step is preferably conducted on a hot plate-style apparatus, although oven curing may be used to obtain equivalent results. Typically, the curing may be conducted at a temperature of 150° C. or greater, and preferably 150 to 450° C. It is more preferred that the curing temperature is 180° C. or greater, still more preferably 200° C. or greater, and even more preferably from 200 to 400° C. The curing time is typically from 10 seconds to 10 minutes, preferably from 30 seconds to 5 minutes, more preferably from 45 seconds to 2 minutes, and still more preferably from 45 to 90 seconds. Optionally, a ramped or a multi-stage curing process may be used. A ramped bake typically begins at a relatively low (e.g., ambient) temperature that is increased at a constant or varied ramp rate to a higher target temperature. A multi-stage curing process involves curing at two or more temperature plateaus, typically a first stage at a lower bake temperature and one or more additional stages at a higher temperature. Conditions for such ramped or multi-stage curing processes are known to those skilled in the art, and may allow for omission of a preceding soft bake process.

After curing of the applied underlayer composition, a photoresist layer is formed over the coated underlayer. As noted above, other intervening layers may be applied between the coated underlayer and the overcoated photoresist layer. In some aspect, the method may further include forming a silicon-containing layer, an organic antireflective coating layer, or a combination thereof, over the coated underlayer prior to forming the photoresist layer.

A wide variety of photoresists may be suitably used in the methods of the invention and are typically positive-tone materials. The particular photoresists to be used will depend on the exposure wavelength used and generally comprise an acid-sensitive matrix polymer, a photoactive component such as a photoacid generator, a solvent, and optional additional components. Suitable photoresists are known to those skilled in the art and are commercially available, for example, various photoresist materials in the UV™ and EPIC™ product families from DuPont Electronics & Industrial. The photoresist can be applied to the substrate by known coating techniques such as described above with reference to the underlayer composition, with spin-coating being typical. A typical thickness for the photoresist layer is from 10 to 300 nm. The photoresist layer is typically next soft baked to minimize the solvent content in the layer, thereby forming a tack-free coating and improving adhesion of the layer to the substrate. The soft bake can be conducted on a hotplate or in an oven, with a hotplate being typical. Typical soft bakes are conducted at a temperature from 70 to 150° C., and a time from 30 to 90 seconds.

The photoresist layer is next exposed to activating radiation through a photomask to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is typically sub-400 nm, and more typically, sub-300 nm, such as 248 nm (KrF), 193 nm (ArF), or an EUV wavelength (e.g., 13.5 nm). In a preferred aspect, the exposure wavelength is 193 nm or an EUV wavelength. The exposure energy is typically from 10 to 100 millijoules per square centimeter (mJ/cm²), depending, for example, on the exposure tool and the components of the photosensitive composition.

Following exposure of the photoresist layer, a post-exposure bake (PEB) is typically performed. The PEB can be conducted, for example, on a hotplate or in an oven. The PEB is typically conducted at a temperature from 70 to 150° C., and a time from 30 to 90 seconds. A latent image defined by the boundary between polarity-switched and unswitched regions (corresponding to exposed and unexposed regions, respectively) is thereby formed. The photoresist layer is next developed to remove the exposed regions of the layer, leaving the unexposed regions forming a patterned photoresist layer. The developer is typically an aqueous alkaline developer, for example, a tetra-alkyl ammonium hydroxide solution such as a tetramethylammonium hydroxide (TMAH) solution, typically a 0.26 Normality (N) (2.38 wt %) solution of TMAH. The developer may be applied by known techniques, for example, spin-coating or puddle coating.

The pattern of the photoresist layer can be transferred to one or more underlying layers including the coated underlayer and to the substrate by appropriate etching techniques, such as by plasma etching using appropriate gas species for each layer being etched. Depending on the number of layers and materials involved, pattern transfer may include multiple etching steps using different etching gases. The patterned photoresist layer, the coated underlayer, and the other optional layers in the lithographic stack may be removed following pattern transfer to the substrate using conventional techniques. Optionally, one or more of the layers of the stack may be removed following, or consumed during, pattern transfer to an underlying layer and prior to pattern transfer to the substrate. For example, pattern transfer to one or more of a silicon-containing layer, an organic antireflective coating layer, or the like may occur after the exposed photoresist layer is developed and before pattern transfer to the coated underlayer. The substrate is then further processed according to known processes in the art to form an electronic device.

Also provided is a coated substrate that includes a layer of the inventive underlayer composition on a substrate; and a photoresist layer disposed on the layer of the underlayer composition. As used herein, the term “cured layer” refers to a layer derived from the underlayer composition after the composition has been disposed on a substrate and subsequently cured to form a coating layer or film. In other words, curing the underlayer composition forms a cured layer derived from the underlayer composition.

Still other aspects provide a layered article including a coated underlayer derived from the inventive underlayer composition. In an embodiment, a layered article may include a substrate; a coated underlayer disposed over the substrate; and a photoresist layer disposed over the coated underlayer.

Underlayers, including coated underlayers prepared from the inventive underlayer composition show good gap filling and strip resistance. For example, the composition can provide good gap fill (complete or substantially complete fill or only very small voids of width less than 50 nm and void % less than 10%) of gaps having an aspect ratio of at least 1.5, at least 1.6, at least 1.7, at least 1.8, at least 1.9, or at least 2 and a width of less than 150, less than 140, less than 130, less than 120, less than 110, or less than 100 nm. The aspect ratio can be less than 100, less than 90, less than 80, and the width can be at least 0.1 nm, at least 0.5 nm, or at least 1 nm. Preferred underlayer compositions of the invention may, as a result, be useful in a variety of semiconductor manufacturing processes

The present inventive concept is further illustrated by the following examples, which are intended to be non-limiting. The compounds and reagents used herein are available commercially except where a procedure is provided below.

### EXAMPLES

### Example 1—Synthesis of Polymers

### Polymer 1

Dimethylterephthalate (22.3 g), dimethyl 5-hydroxyisophthalate (18 g), 1,3,5-tris(2-hydroxyethyl)isocyanurate (53 g), 2-hydroxyisobutyrinc acid (18 g), para-toluenesulfonic acid (2.1 g) and anisole (80 g) were charged into 250-mL three-neck, round bottom flask fitted with a mechanical stirrer, temperature control box and probe, heating mantle, condenser, Dean-Stark trap and nitrogen purge inlet. The reaction was heated to substantial reflux (120-150° C.) followed by gradual increase to a peak temperature of 150° C. for 6 hours. The cooled solution was diluted using 355 g of tetrahydrofuran (THF) and then precipitated using isopropanol. The polymer was collected by filtration through a Buchner funnel, air-dried then dried in vacuo between 40-70° C. The dried polymer had the following characteristics: weight average molecular weight (Mw): 2620, polydispersity (PDI): 1.3.

### Polymer 2

A 500 mL round bottom flask was charged with tris(2-hydroxyethyl)isocyanurate (37.8 g), tris(2-carboxyethyl)isocyanurate (16.6 g), dibutylnaphthalene dicarboxylate (30.5 g), para-toluenesulfonic acid (1.1 g), anisole (80 g) and 1-butanol (100 g). The mixture was then heated to 140-160° C., and the contents were vigorously stirred. Butanol along with anisole was slowly distilled out of the reaction flask. The polymer solution was then diluted by adding tetrahydrofuran (100 g), and the mixture was precipitated upon the addition of isopropanol. Precipitated polymer solid was collected and dried under vacuum at 40-60° C. for overnight. The dried polymer had the following characteristics: weight average molecular weight (Mw): 6570, polydispersity (PDI): 1.6.

### Example 2—Preparation of Formulations

Each composition was prepared by charging the components into a clean bottle without regard to the order of addition. Tetramethoxyglycouril (TMGU) and paratoluene sulfonic acid-trimethylpyridinium salt (“pTSA-TMP”; as disclosed in US20170336709A1) were used as the crosslinker and the thermal acid generator (TAG) across all samples in amounts of 0.6 g TMGU and 0.05 g pTSA-TMP. The polymer was used in an amount of 3.35 g. The polymer type used, the additive used, the amount of additive used, and the amount solvent used are set forth in Table 1. The samples were placed on shaker for at least 4 hours until all materials were completely dissolved. Each sample was then passed through a 0.45 m PTFE membrane filter into a clean bottle before coating. Methyl 2-hydroxyisobutyrate (HBM) had been used to formulate the examples. The used additives were purchased via commercial sources such as Tokyo Chemical Industry Co. Ltd. Additives 12, 22, 34, 42, 51, and 55 have the structures are shown herein. Comparative additives 61 and 62 have the structures

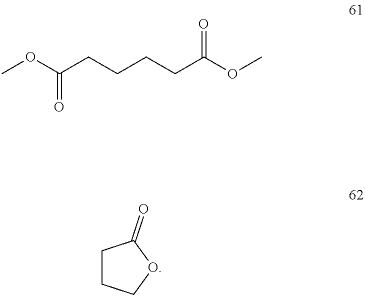

TABLE 1

| | | | Amount of | | |
|---|---|---|---|---|---|
| Sample | Polymer | Additive | Additive | Amount of Solvent | |
| Example 1 | Polymer 1 | 12 | 4.8 g | 91.2 | g |
| Example 2 | Polymer 1 | 12 | 9.6 g | 86.4 | g |
| Example 3 | Polymer 1 | 22 | 4.8 g | 91.2 | g |
| Example 4 | Polymer 1 | 22 | 9.6 g | 86.4 | g |
| Example 5 | Polymer 1 | 32 | 4.8 g | 91.2 | g |
| Example 6 | Polymer 1 | 32 | 9.6 g | 86.4 | g |
| Example 7 | Polymer 1 | 42 | 4.8 g | 91.2 | g |
| Example 8 | Polymer 1 | 42 | 9.6 g | 86.4 | g |
| Example 9 | Polymer 1 | 51 | 4.8 g | 91.2 | g |
| Example 10 | Polymer 1 | 51 | 9.6 g | 86.4 | g |
| Example 11 | Polymer 1 | 55 | 4.8 g | 91.2 | g |
| Example 12 | Polymer 1 | 55 | 9.6 g | 86.4 | g |
| Example 13 | Polymer 2 | 12 | 4.8 g | 91.2 | g |
| Example 14 | Polymer 2 | 12 | 9.6 g | 86.4 | g |
| Example 15 | Polymer 2 | 22 | 4.8 g | 91.2 | g |
| Example 16 | Polymer 2 | 22 | 9.6 g | 86.4 | g |
| Example 17 | Polymer 2 | 32 | 4.8 g | 91.2 | g |
| Example 18 | Polymer 2 | 32 | 9.6 g | 86.4 | g |
| Example 19 | Polymer 2 | 42 | 4.8 g | 91.2 | g |
| Example 20 | Polymer 2 | 42 | 9.6 g | 86.4 | g |
| Example 21 | Polymer 2 | 51 | 4.8 g | 91.2 | g |
| Example 22 | Polymer 2 | 51 | 9.6 g | 86.4 | g |
| Example 23 | Polymer 2 | 55 | 4.8 g | 91.2 | g |
| Example 24 | Polymer 2 | 55 | 9.6 g | 86.4 | g |
| Comparative | Polymer 1 | — | — | 96 | g |
| example 1 | | | | | |
| Comparative | Polymer 1 | 61 | 4.8 g | 91.2 | g |
| example 2 | | | | | |
| Comparative | Polymer 1 | 62 | 4.8 g | 91.2 | g |
| example 3 | | | | | |
| Comparative | Polymer 2 | — | — | 96 | g |
| example 4 | | | | | |
| Comparative | Polymer 2 | 61 | 4.8 g | 91.2 | g |
| example 5 | | | | | |
| Comparative | Polymer 2 | 62 | 4.8 g | 91.2 | g |

example 6

### Example 3—Evaluation of Solvent Strip Resistance and Gap-Filling Performance

A prepared composition was spin-coated onto an 8-inch silicon wafer at 1500 rpm using a spinner and the wafer was heated at 205° C. for 60 seconds on a hot plate to form a thin film with thickness of 100 nm. Then the thin film was exposed to 30 mL of a mixture of propylene glycol methyl ether (PGME) 1-methoxy-2-propanyl acetate (PGMEA) in 70/30 wt/wt % for 90 seconds or 2.38 wt % aqueous solution of Tetramethylammonium hydroxide (TMAH) for 60 seconds, spun-dried at 4000 rpm for 60 seconds and post-baked at 110° C. for 60 seconds on a hot plate. The thickness measurement was carried out using Therma-wave Opti-probe 5250. The thickness of lost film by stripping from organic solvent (strip loss) was calculated as the difference between the thickness of an initially coated film and an exposed & post baked film. The result, which is summarized in Table 2, showed that the introduction of additives into the formulation did not cause significant loss of crosslinked film by solvents.

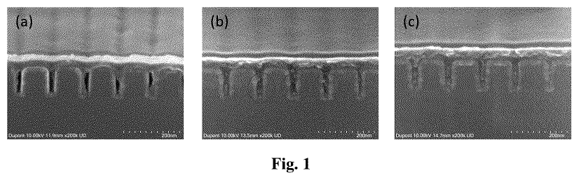

12-inch wafers with TiN-deposited (via LPCVD) silicon substrate with trench patterns were provided. The patterns included trenches with 40 nm width and 100 nm height. The underlayer compositions as described in the above were spin-coated over the pattern surface of wafer at 1500 rpm and cured at 205° C. for 1 minute to give a film thickness of 100 nm. The trench patterns after curing were inspected using vertical scanning electron microscope (V-SEM) to evaluate gap-filling performance of formulation examples, and the result is shown as FIG. 1(a)-(c) and Table 2. FIG. 1(a) is of comparative example 1 showing significant void in the trenches, FIG. 1(b) is of Example showing improved filling with some small remaining voids. FIG. 1(c) is of Example 3 showing completely filled trenches. While comparative examples without the additive showed voids in the trenches, the filling of trenches were improved upon the addition of esteric additives.

TABLE 2

| | Strip loss by | Strip loss by | Gap-filling |
|---|---|---|---|
| Sample | PGME/PGMEA | TMAH | result |
| Example 1 | <5 Å | <5 Å | Good |
| Example 2 | <5 Å | <5 Å | Good |
| Example 3 | <5 Å | <5 Å | Good |
| Example 4 | <5 Å | <5 Å | Good |
| Example 5 | <5 Å | <5 Å | Good |
| Example 6 | <5 Å | <5 Å | Good |
| Example 7 | <5 Å | <5 Å | Good |
| Example 8 | <5 Å | <5 Å | Good |
| Example 9 | <5 Å | <5 Å | Good |
| Example 10 | <5 Å | <5 Å | Good |
| Example 11 | <5 Å | <5 Å | Good |
| Example 12 | <5 Å | <5 Å | Good |
| Example 13 | <5 Å | <5 Å | Good |
| Example 14 | <5 Å | <5 Å | Good |
| Example 15 | <5 Å | <5 Å | Good |
| Example 16 | <5 Å | <5 Å | Good |
| Example 17 | <5 Å | <5 Å | Good |
| Example 18 | <5 Å | <5 Å | Good |
| Example 19 | <5 Å | <5 Å | Good |
| Example 20 | <5 Å | <5 Å | Good |
| Example 21 | <5 Å | <5 Å | Good |
| Example 22 | <5 Å | <5 Å | Good |
| Example 23 | <5 Å | <5 Å | Good |
| Example 24 | <5 Å | <5 Å | Good |
| Comparative example 1 | <5 Å | <5 Å | Voids |
| Comparative example 2 | <5 Å | <5 Å | Voids |
| Comparative example 3 | <5 Å | <5 Å | Improved |
| Comparative example 4 | <5 Å | <5 Å | Voids |
| Comparative example 5 | <5 Å | <5 Å | Voids |
| Comparative example 6 | <5 Å | <5 Å | Improved |

As used herein, the term “and/or” includes all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects. The terms “about”, “substantially” and “generally” are intended to include the degree of error associated with measurement of the particular quantity based upon the equipment available at the time of filing the application. For example, “about” and/or “substantially” and/or “generally” can include a range of ±8% of a given value.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g. “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function and/or objectives of the present disclosure.

Unless specified to the contrary herein, all test standards are the most recent standard in effect as of the filing date of this application, or, if priority is claimed, the filing date of the earliest priority application in which the test standard appears.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O—”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O—”; “alkenylene group” refers to an alkenyl group having a valence of at least two; “cycloalkenyl group” refers to a cycloalkyl group having at least one carbon-carbon double bond; “alkynyl group” refers to a monovalent hydrocarbon group having at least one carbon-carbon triple bond; the term “aromatic group” denotes the conventional idea of aromaticity as defined in the literature, in particular in IUPAC 19, and refers to a monocyclic or polycyclic aromatic ring system that includes carbon atoms in the ring or rings, and optionally may include one or more heteroatoms independently selected from N, O, and S instead of a carbon atom or carbon atoms in the ring or rings; “aryl group” refers to a monovalent, monocyclic or polycyclic aromatic group containing only carbon atoms in the aromatic ring or rings, and may include a group with an aromatic ring fused to at least one cycloalkyl or heterocycloalkyl ring; “arylene group” refers to an aryl group having a valence of at least two; “alkylaryl group” refers to an aryl group that has been substituted with an alkyl group; “arylalkyl group” refers to an alkyl group that has been substituted with an aryl group; “aryloxy group” refers to “aryl-O—”; and “arylthio group” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently selected from N, O, S, Si, or P; “heteroatom-containing group” refers to a substituent group that includes at least one heteroatom; “heteroalkyl group” refers to an alkyl group having 1-4 heteroatoms instead of carbon atoms; “heterocycloalkyl group” refers to a cycloalkyl group with one or more N, O or S atoms instead of carbon atoms; “heterocycloalkylene group” refers to a heterocycloalkyl group having a valence of at least two; “heteroaryl group” refers to an aryl group having 1 to 3 separate or fused rings with one or more N, O or S atoms as ring members instead of carbon atoms; and “heteroarylene group” refers to a heteroaryl group having a valence of at least two.

“Substituted” or “substituent group” means that at least one hydrogen atom on the group is replaced with another group, provided that the designated atom's normal valence is not exceeded. When the substituent is oxo (i.e., ═O), then two hydrogens on the carbon atom are replaced. Combinations of two or more substituents or variables are permissible. For example, the term “substituted” may refer to the stated hydrocarbon moiety with two, three, or four of the same or different substituent groups. Exemplary groups that may be present on a “substituted” position include, but are not limited to, nitro (—NO₂), cyano (—CN), hydroxyl (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, C₂₋₆ alkyl ester (—C(═O)O-alkyl or —OC(═O)-alkyl), C₇₋₁₃ aryl ester (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

As used herein, the terms “polymer” and “polymeric” refer to a polymeric material that includes one or more repeating units, where the repeating units may be the same or different from each other. Thus, the disclosed polymers and polymeric materials of the invention can be referred to herein as a “polymer” or a “copolymer.” It is to be further understand that the terms “polymer” and “polymeric” further include oligomers. As used herein, each of the one or more different repeating units are present in the polymeric material at least two times. In other words, a polymeric material including one repeating unit includes a first repeating unit that is present in an amount of two or more, and, for example, a polymeric material including two repeating units includes a first repeating unit that is present in an amount of two or more, and a second repeating unit that is present in an amount of two or more.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A coating composition for use with an overcoated photoresist composition, comprising:
a thermally crosslinkable resin;
a compound of the following general formula (1): 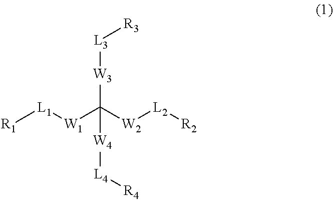
wherein: W₁, W₂, W₃, and W₄ are independently a single bond or substituted or unsubstituted C₁₋₅ alkylene; L₁ and L₂ are each an ester group; L₃ and L₄ are independently a single bond or a group chosen from carbonyl, or an ester group; R₁ and R₂ are independently hydrogen, halogen, substituted or unsubstituted C₁₋₁₀ alkyl, or substituted or unsubstituted C₃₋₁₀ cycloalkyl; R₃ and R₄ are independently hydrogen, halogen, hydroxyl, substituted or unsubstituted C₁₋₁₀ alkyl, or substituted or unsubstituted C₃₋₁₀ cycloalkyl; and
a solvent.

2. The coating composition of claim 1, wherein R₃ is hydroxyl.

3. The coating composition of claim 1, wherein W₃ and L₃ are each a single bond.

4. The coating composition of claim 1, wherein L₃ is an ester group.

5. The coating composition of claim 1, wherein the compound of general formula (1) is present in the composition in an amount of from 0.5 to 20 wt % based on total solids of the coating composition.

6. The coating composition of claim 1, wherein the solvent is an organic-based solvent.

7. The coating composition of claim 1, further comprising a crosslinker component, a thermal acid generator compound, or both that are each distinct from the thermally crosslinkable resin and the compound of general formula (1).

8. A pattern formation method, comprising:
(a) forming a underlayer from a coating composition of claim 1 on a substrate;
(b) applying a photoresist layer over the underlayer;
(c) exposing the photoresist layer to activating radiation; and
(d) developing the exposed photoresist layer to provide a resist relief image.

9. The pattern formation method of claim 8, wherein the substrate comprises gaps having an aspect ratio of 2 or more and a width of 100 nanometers or less.
